(19) United States
(12) Patent Application Publication
(10) Pub. No.: US 2013/0249073 A1
(43) Pub. Date: Sep. 26, 2013

(54) INTEGRATED CIRCUIT PACKAGING SYSTEM WITH SUPPORT STRUCTURE AND METHOD OF MANUFACTURE THEREOF

(71) Applicants: Hsin Hung Chen, New Taipei City (TW); Chien Chen Lee, Jhubei City (TW)

(72) Inventors: Hsin Hung Chen, New Taipei City (TW); Chien Chen Lee, Jhubei City (TW)

(21) Appl. No.: 13/427,221

(22) Filed: Mar. 22, 2012

(51) Int. Cl. H01L 23/34; H01L 21/56; H01L 21/50

(52) U.S. Cl. 257/706; 438/125; 438/126; 257/E23.08; 257/E21.499; 257/E21.502

(57) ABSTRACT

A method of manufacture of an integrated circuit packaging system includes: providing a single-layer support structure having a structure non-horizontal surface; forming a single-layer contact coplanar with the single-layer support structure, the single-layer contact having a contact non-horizontal surface; forming a single-layer insulation coplanar with the single-layer contact and horizontally between the structure non-horizontal surface and the contact non-horizontal surface; forming an upper support pad over the single-layer insulation and directly on the single-layer support structure; and mounting an integrated circuit over the upper support pad.

### TECHNICAL FIELD

The present invention relates generally to an integrated circuit packaging system, and more particularly to a system for an integrated circuit packaging system with support structure.

### BACKGROUND ART

Increased miniaturization of components, greater packaging density of integrated circuits (“ICs”), higher performance, and lower cost are ongoing goals of the computer industry. Semiconductor package structures continue to advance toward miniaturization, to increase the density of the components that are packaged therein while decreasing the sizes of the products that are made therefrom. This is in response to continually increasing demands on information and communication products for ever-reduced sizes, thicknesses, and costs, along with ever-increasing performance.

These increasing requirements for miniaturization are particularly noteworthy, for example, in portable information and communication devices such as cellular phones, hands-free cellular phone headsets, personal data assistants (“PDA's”), camcorders, notebook computers, and so forth. All of these devices continue to be made smaller and thinner to improve their portability. Accordingly, large-scale IC (“LSI”) packages that are incorporated into these devices are required to be made smaller and thinner. The package configurations that house and protect LSI require them to be made smaller and thinner as well.

Consumer electronics requirements demand more integrated circuits in an integrated circuit package while paradoxically providing less physical space in the system for the increased integrated circuits content. Continuous cost reduction is another requirement. Some technologies primarily focus on integrating more functions into each integrated circuit. Other technologies focus on stacking these integrated circuits into a single package. While these approaches provide more functions within an integrated circuit, they do not fully address the requirements for integration and cost reduction.

Thus, a need still remains for an integrated circuit packaging system providing integration, space savings, and low cost manufacturing. In view of the ever-increasing need to increase density of integrated circuits and particularly portable electronic products, it is increasingly critical that answers be found to these problems. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a single-layer support structure having a structure non-horizontal surface; forming a single-layer contact coplanar with the single-layer support structure, the single-layer contact having a contact non-horizontal surface; forming a single-layer insulation coplanar with the single-layer contact and horizontally between the structure non-horizontal surface and the contact non-horizontal surface; forming an upper support pad over the single-layer insulation and directly on the single-layer support structure; and mounting an integrated circuit over the upper support pad.

The present invention provides an integrated circuit packaging system, including: a single-layer support structure having a structure non-horizontal surface; a single-layer contact coplanar with the single-layer support structure, the single-layer contact having a contact non-horizontal surface; a single-layer insulation coplanar with the single-layer contact and horizontally between the structure non-horizontal surface and the contact non-horizontal surface; an upper support pad over the single-layer insulation and directly on the single-layer support structure; and an integrated circuit over the upper support pad.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system taken along line 1-1 of FIG. 2 in a first embodiment of the present invention.

FIG. 2 is a bottom view of the integrated circuit packaging system.

FIG. 3 is a cross-sectional view of the integrated circuit packaging system in a conductor-formation phase of manufacture.

FIG. 4 is the structure of FIG. 3 in a mask-formation phase.

FIG. 5 is the structure of FIG. 4 in a mask-patterning phase.

FIG. 6 is the structure of FIG. 5 in a conductor-removal phase.

FIG. 7 is the structure of FIG. 6 in an insulator-formation phase.

FIG. 8 is the structure of FIG. 7 in a mask-removal phase.

FIG. 9 is the structure of FIG. 8 in a carrier-removal and pad-formation phase.

FIG. 10 is the structure of FIG. 9 in a mounting phase.

FIG. 11 is the structure of FIG. 10 in an attachment phase.

FIG. 12 is the structure of FIG. 11 in a molding phase.

FIG. 13 is a cross-sectional view of an integrated circuit packaging system in a second embodiment of the present invention.

FIG. 14 is a cross-sectional view of an integrated circuit packaging system in a third embodiment of the present invention.

FIG. 15 is a cross-sectional view of an integrated circuit packaging system in a fourth embodiment of the present invention.

FIG. 16 is a flow chart of a method of manufacture of the integrated circuit packaging system of FIG. 1 in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane of an active surface of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is contact between elements. The term “directly on” means that there is direct contact between one element and another element without an intervening element.

The term “active side” refers to a side of a die, a module, a package, or an electronic structure having active circuitry fabricated thereon or having elements for connection to the active circuitry within the die, the module, the package, or the electronic structure. The term “processing” as used herein includes deposition of material or photoresist, patterning, exposure, development, etching, cleaning, and/or removal of the material or photoresist as required in forming a described structure.

As light, thin, small overall volume and high efficiency of consumer electronic and communication products have increasing requirements, chip packages should provide superior electrical properties, small overall volume, and a large number of input/output (I/O) ports. Substrates used in these chip packages posses multiple metal and dielectric layers to form traces and vias to connect electrically or thermally and are made by more and complex processes with high cost in process and material. Therefore, it is desirable to develop a substrate possessing a thin profile made by reduced materials and less complex processes to further form a thin package. Embodiments of the present invention provide answers or solutions to these requirements and problems.

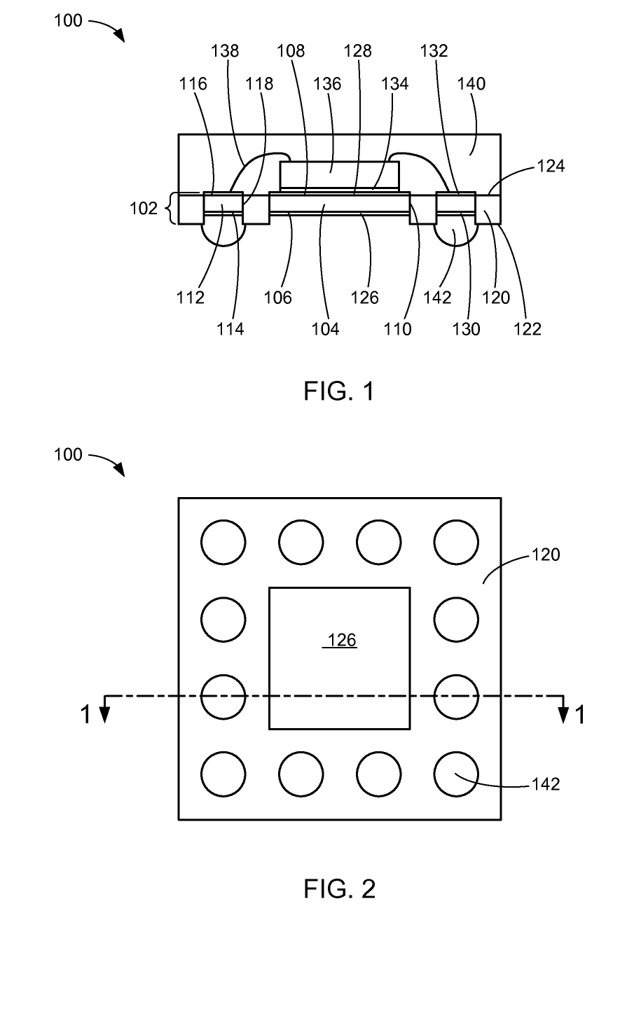

Referring now to FIG. 1, therein is shown a cross-sectional view of an integrated circuit packaging system 100 taken along line 1-1 of FIG. 2 in a first embodiment of the present invention. The integrated circuit packaging system 100 can include electronic semiconductor packages.

The integrated circuit packaging system 100 can include a single-layer substrate 102, which is defined as a support structure having a single core metal layer for mounting and connecting a semiconductor device thereto including providing electrical connections through the support structure. The single-layer substrate 102 can represent a single metal layer substrate.

The single-layer substrate 102 can include a single-layer support structure 104 having a structure lower surface 106, a structure upper surface 108, and a structure non-horizontal surface 110. The single-layer substrate 102 can include single-layer contacts 112, each of which having a contact lower surface 114, a contact upper surface 116, and a contact non-horizontal surface 118. The single-layer substrate 102 can include a single-layer insulation 120 having an insulation lower surface 122 and an insulation upper surface 124. The single-layer substrate 102 can include a lower support pad 126, an upper support pad 128, lower contact pads 130, and upper contact pads 132.

The single-layer support structure 104 is defined as a structure having only one contiguously solid layer of a conductive material. The single-layer support structure 104 provides support for mounting and attaching a semiconductor device. The single-layer contacts 112 are defined as structures having only one contiguously solid layer of a conductive material. The single-layer contacts 112 provide connection sites for attaching electrical connectors thereto.

The single-layer insulation 120 is defined as a structure having only one solid layer of an insulation material. The single-layer insulation 120 provides electrical isolation between the single-layer support structure 104 and the single-layer contacts 112 and between one of the single-layer contacts 112 and another of the single-layer contacts 112. The single-layer insulation 120 can be formed only horizontally between the single-layer support structure 104 and the single-layer contacts 112 and only horizontally between one of the single-layer contacts 112 and another of the single-layer contacts 112.

The single-layer insulation 120 can be formed directly on the structure non-horizontal surface 110 and the contact non-horizontal surface 118. As such, the single-layer insulation 120 is not directly over the single-layer support structure 104 and the single-layer contacts 112. The single-layer insulation 120 can be only horizontally adjacent the structure non-horizontal surface 110 and the contact non-horizontal surface 118 and not covering the structure lower surface 106, the structure upper surface 108, the contact lower surface 114, and the contact upper surface 116.

The single-layer insulation 120 can be formed vertically extending beyond the single-layer support structure 104 and the single-layer contacts 112. The insulation lower surface 122 can be below the structure lower surface 106 and the contact lower surface 114.

The structure lower surface 106 and the contact lower surface 114 can be coplanar with each other. The structure upper surface 108, the contact upper surface 116, and the insulation upper surface 124 can be coplanar with each other. The lower support pad 126 and the upper support pad 128 can be formed directly on the structure lower surface 106 and the structure upper surface 108, respectively. One of the lower contact pads 130 and one of the upper contact pads 132 can be formed directly on the contact lower surface 114 and the contact upper surface 116, respectively.

The structure non-horizontal surface 110 and the contact non-horizontal surface 118 can include a physical characteristic of being formed with a single layer of an electrically conductive material partially removed by a removal process. The physical characteristic can include a rough surface, an uneven surface, a concave surface, removal marks, and etched marks. The physical characteristic provides improved adhesion for the single-layer insulation 120 to form directly on the structure non-horizontal surface 110 and the contact non-horizontal surface 118.

The integrated circuit packaging system 100 can include an attach layer 134 for mounting an integrated circuit 136 over the single-layer support structure 104. The integrated circuit packaging system 100 can include internal connectors 138 attached to the integrated circuit 136 and the upper contact pads 132. The integrated circuit packaging system 100 can include an encapsulation 140 over the single-layer support structure 104, the single-layer contacts 112, the single-layer insulation 120, the integrated circuit 136, and the internal connectors 138. The integrated circuit packaging system 100 can include external connectors 142 attached to the single-layer insulation 120 and the lower contact pads 130.

The integrated circuit packaging system 100 can represent a thin package with a single metal layer substrate with each of the single-layer support structure 104 and the single-layer contacts 112 having a predetermined vertical height. The single-layer support structure 104 and the single-layer contacts 112 having the predetermined vertical height provides a light, very thin, small overall volume substrate with only one layer thickness of a single metal layer.

For example, the predetermined vertical height can be approximately less than or equal to one sixth of a vertical height of the integrated circuit packaging system 100 or approximately less than or equal to one third of a vertical height of the encapsulation 140. Also for example, the predetermined vertical height can be in an approximate range of 5 to 68.6 micrometers (um) when the single-layer support structure 104 and the single-layer contacts 112 are formed with a copper foil having a thickness in an approximate range of ⅛ to 2 ounces per square foot (oz/ft²).

It has been discovered that the single-layer insulation 120 provides improved structural integrity with the single-layer insulation 120 horizontally between the structure non-horizontal surface 110 and the contact non-horizontal surface 118 or horizontally between the contact non-horizontal surface 118 and another of the contact non-horizontal surface 118 to provide firm mounting and attaching support as well as provide process advantage and cost advantage.

It has also been discovered that the structure upper surface 108, the contact upper surface 116, and the insulation upper surface 124 coplanar with each other provides improved reduction of package height profile since the single-layer insulation 120 is not formed directly over the single-layer support structure 104 and the single-layer contacts 112.

It has further been discovered that the single-layer insulation 120 having the extension that vertically extends beyond the single-layer support structure 104 and the single-layer contacts 112 provides improved reliability because the extension eliminates electrical shorts among the single-layer support structure 104 and the single-layer contacts 112.

It has further been discovered that the structure non-horizontal surface 110 and the contact non-horizontal surface 118 having the physical characteristic described above provides improved structural integrity by providing improved adhesion for the single-layer insulation 120 to form thereby eliminating the single-layer support structure 104 and the single-layer contacts 112 from being pulled out.

Referring now to FIG. 2, therein is shown a bottom view of the integrated circuit packaging system 100. The bottom view depicts a peripheral array of the external connectors 142 along a perimeter of the single-layer insulation 120. The peripheral array of the external connectors 142 can be formed within a periphery of the single-layer insulation 120. The peripheral array of the external connectors 142 can surround the lower support pad 126.

For illustrative purposes, the peripheral array is shown with one row of the external connectors 142, although it is understood that the peripheral array can be formed with any configuration. For example, the peripheral array can be formed with multiple rows of the external connectors 142.

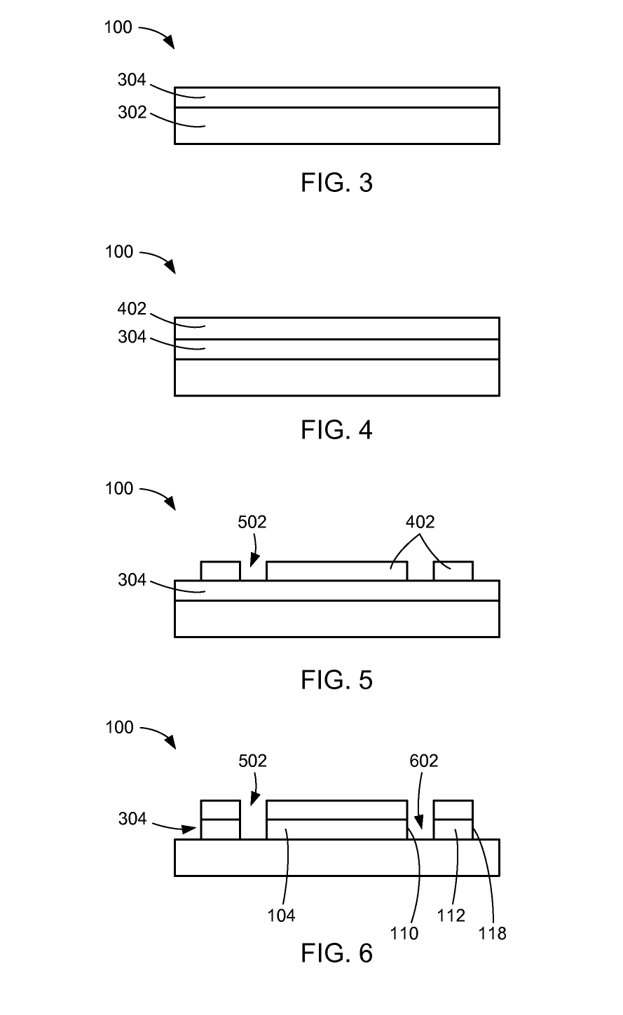

Referring now to FIG. 3, therein is shown a cross-sectional view of the integrated circuit packaging system 100 in a conductor-formation phase of manufacture. The integrated circuit packaging system 100 can include a carrier 302 to provide support for a conductor 304 to form directly thereon. The conductor 304 can be formed with an electrically conductive material including copper (Cu), a metallic material, or a metal alloy. The conductor 304 can represent a single core metal layer.

Referring now to FIG. 4, therein is shown the structure of FIG. 3 in a mask-formation phase. The integrated circuit packaging system 100 can include a mask 402 formed or taped directly on the conductor 304. The mask 402 can be unaffected by the removal process including an etching process to protect a portion of the conductor 304 during the removal process. For example, the mask 402 can represent a dry film, a resist mask, a positive resist mask, or a mask resistant to an etching treatment.

Referring now to FIG. 5, therein is shown the structure of FIG. 4 in a mask-patterning phase. The mask 402 can be partially removed to form mask holes 502 through the mask 402. The mask holes 502 can expose portions of the conductor 304. The mask 402 can be partially removed with a removal process including an exposure and development process.

Referring now to FIG. 6, therein is shown the structure of FIG. 5 in a conductor-removal phase. Portions of the conductor 304 exposed by the mask holes 502 can be removed to form a single patterned metal layer including the single-layer support structure 104 and the single-layer contacts 112 adjacent thereto. The single-layer support structure 104 and the single-layer contacts 112 are separate from each other by openings 602 of the conductor 304 with the portions of the conductor 304 removed.

The portions of the conductor 304 can be removed with the removal process including an etching process or a chemical removal process. The structure non-horizontal surface 110 and the contact non-horizontal surface 118 can include the physical characteristic previously described characteristic of being formed with the conductor 304 partially removed by the removal process.

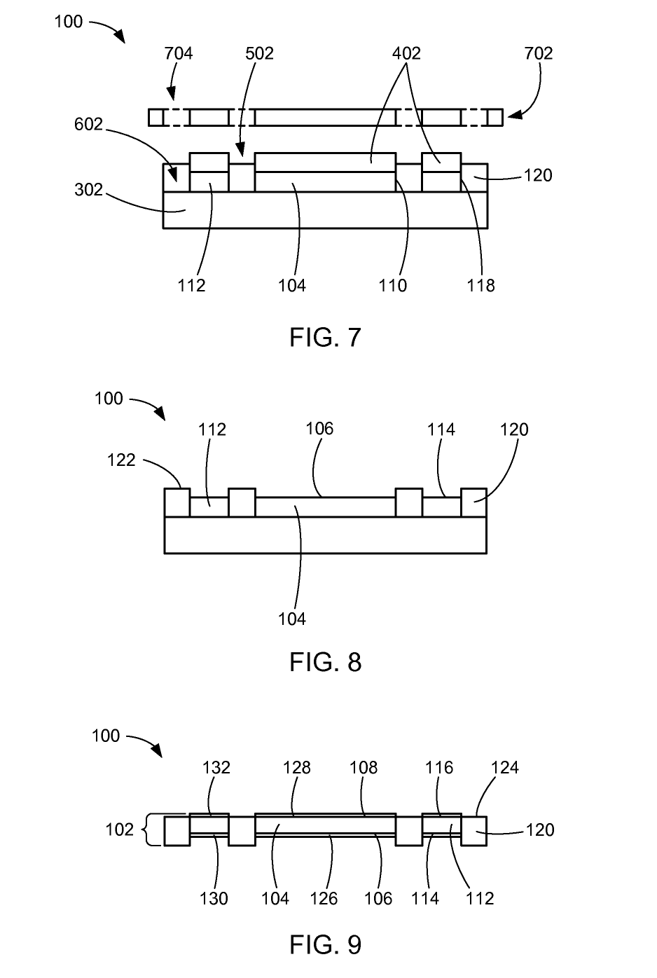

Referring now to FIG. 7, therein is shown the structure of FIG. 6 in an insulator-formation phase. The single-layer insulation 120 can be formed by an insulator-formation process including resist lamination or coating including pre-cure or post-cure, exposure, development, and stripping or etching.

The single-layer insulation 120 can be formed within the openings 602 or in a space between the single-layer support structure 104 and the single-layer contacts 112. The single-layer insulation 120 can be adjacent the single-layer support structure 104 and the single-layer contacts 112.

The single-layer insulation 120 can be formed directly on a top extent of the carrier 302, the structure non-horizontal surface 110, the contact non-horizontal surface 118 of each of the single-layer contacts 112, and a portion of a non-horizontal surface of the mask 402. The structure non-horizontal surface 110 and the contact non-horizontal surface 118 having the physical characteristic previously described can strengthen the single-layer insulation 120.

The single-layer insulation 120 can be formed with an insulation material including a dielectric, a solder mask, a liquid crystal polymer (LCP), a molding compound, a polyimide, an epoxy, bismaleimide triazine (BT) resin, or other resins or films. For example, the single-layer insulation 120 can represent a layer of a patterned dielectric material.

The integrated circuit packaging system 100 can optionally include a stencil 702 having stencil holes 704, shown in a region of the stencil 702 with dash lines. The stencil 702 can be placed or positioned over the mask 402 such that the stencil holes 704 are vertically aligned with the mask holes 502 and the openings 602 to form the single-layer insulation 120.

Referring now to FIG. 8, therein is shown the structure of FIG. 7 in a mask-removal phase. The mask 402 of FIG. 4 can be removed or stripped after the single-layer insulation 120 is formed and cured. FIG. 8 depicts the single-layer support structure 104, the single-layer contacts 112, and the single-layer insulation 120 in a vertically flipped position.

For illustrative purposes, the single-layer insulation 120 is shown having an extension or a protrusion vertically extending beyond the single-layer support structure 104 and the single-layer contacts 112, although it is understood that the single-layer insulation 120 can be formed in any configuration. For example, the extension or the protrusion of the single-layer insulation 120 can optionally be removed to form the insulation lower surface 122 leveled or coplanar with the structure lower surface 106 and the contact lower surface 114. In this example, the insulation lower surface 122 can include a removal mark including etched marks or polished marks characteristic of the portion of the single-layer insulation 120 removed.

Referring now to FIG. 9, therein is shown the structure of FIG. 8 in a carrier-removal and pad-formation phase. FIG. 9 depicts the single-layer support structure 104, the single-layer contacts 112, and the single-layer insulation 120 of FIG. 8 in a vertically flipped position. The carrier 302 of FIG. 3 can be removed to expose the structure upper surface 108, the contact upper surface 116, and the insulation upper surface 124.

The lower support pad 126, the upper support pad 128, the lower contact pads 130, and the upper contact pads 132 can be formed in a variety of manners. For example, the lower support pad 126 and the lower contact pads 130 can be formed before the carrier 302 is removed, and the upper support pad 128 and the upper contact pads 132 can be formed after the carrier 302 is removed. Also for example, the lower support pad 126, the upper support pad 128, the lower contact pads 130, and the upper contact pads 132 can be simultaneously formed after the carrier 302 is removed.

The structure upper surface 108, the contact upper surface 116, and the insulation upper surface 124 can be coplanar with each other. The lower support pad 126 and the lower contact pads 130 can be formed directly on the structure lower surface 106 and the contact lower surface 114, respectively. The upper support pad 128 and the upper contact pads 132 can be formed directly on the structure upper surface 108 and the contact upper surface 116, respectively. The lower support pad 126 and the upper support pad 128 can represent a thermal contact pad and a die support pad, respectively. The lower contact pads 130 and the upper contact pads 132 can represent contact pads.

The lower support pad 126, the upper support pad 128, the lower contact pads 130, and the upper contact pads 132 can include surface finish layers (not shown). The surface finish layers can be formed at bottom extents of the lower support pad 126 and the lower contact pads 130 and top extents of the upper support pad 128 and the upper contact pads 132. The surface finish layers can be formed with a finish layer-formation process including surface treatment.

The surface finish layers can be formed with a conductive material including nickel (Ni), gold (Au), palladium (Pd), silver (Ag), tin (Sn), Lead (Pb), Organic Solderability Preservative (OSP), a metallic material, a metal alloy, or a combination thereof. Each of the surface finish layers can be formed with any number of layers of the conductive material. For example, the surface finish layers can include Ni—Au, Ni—Pd—Au, Ni—Ag, Au, Sn, Sn—Pb alloy, Ag, OSP, or any combination thereof.

The single-layer substrate 102 having the single-layer support structure 104, the single-layer contacts 112, and the single-layer insulation 120 provides a low-cost substrate with only one layer thickness of a single metal layer. Therefore, the single-layer substrate 102 can be formed with reduced substrate processes and material consumption. The single-layer substrate 102 can represent an instance or a unit of a support frame or an array of substrates. The support frame or the array can include multiple instances or units of the single-layer substrate 102.

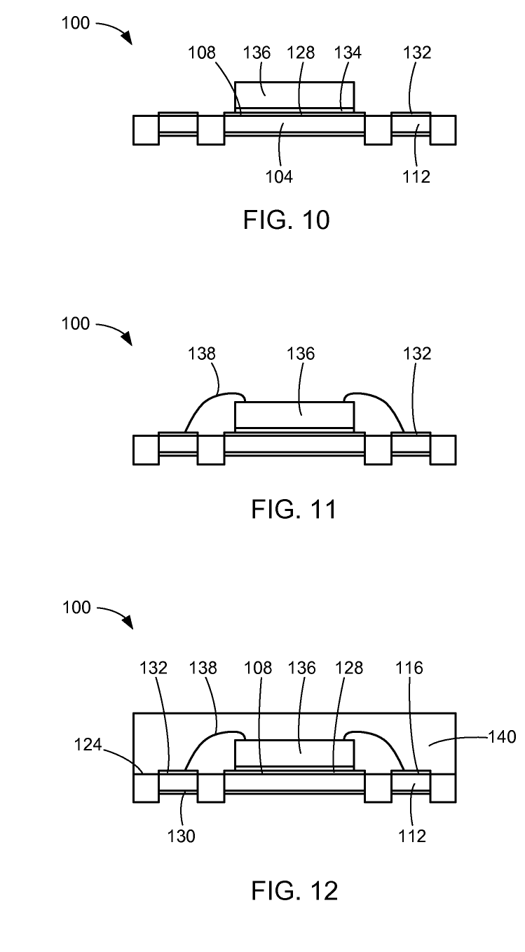

Referring now to FIG. 10, therein is shown the structure of FIG. 9 in a mounting phase. The integrated circuit 136 can be mounted directly over the single-layer support structure 104 with the attach layer 134 attached to an inactive side of the integrated circuit 136 and the upper support pad 128. The attach layer 134 can be formed with an attach material including an adhesive material.

The integrated circuit 136 can represent a semiconductor device including an integrated circuit die or a wirebond integrated circuit. The structure upper surface 108 provides a mounting region, such as a die receiving area, adjacent the single-layer contacts 112 and the upper contact pads 132.

Referring now to FIG. 11, therein is shown the structure of FIG. 10 in an attachment phase. The internal connectors 138 can be attached to an active side of the integrated circuit 136 and the upper contact pads 132. The internal connectors 138 can represent electrical connectors including bond wires.

Referring now to FIG. 12, therein is shown the structure of FIG. 11 in a molding phase. The encapsulation 140 can be formed with a molding material including a molding compound. The encapsulation 140 can represent a package body or a molded structure of a semiconductor package.

The encapsulation 140 can be formed over the structure upper surface 108, the contact upper surface 116, and the insulation upper surface 124. The encapsulation 140 can be formed covering the insulation upper surface 124, the upper support pad 128, the upper contact pads 132, the surface finish layers, the integrated circuit 136, and the internal connectors 138. A bottom extent of the encapsulation 140 can be coplanar with the insulation upper surface 124, the structure upper surface 108, and the contact upper surface 116.

Package singulation can be performed in a subsequent phase. The package singulation can include mechanical or optical means, such as cutting, sawing, laser scribing, or any other singulation processes, to produce individual package units of the integrated circuit packaging system 100.

In a subsequent phase, the external connectors 142 of FIG. 1 can be selectively connected or attached to the lower contact pads 130. Electrical connectivity between the integrated circuit 136 and an external system (not shown) can be provided through the internal connectors 138, the upper contact pads 132, the single-layer contacts 112, the lower contact pads 130, and the external connectors 142.

The external connectors 142 can be formed with an electrically conductive material including solder, a metallic material, or a metal alloy. The external connectors 142 can be formed with a connector-formation process including mounting or printing. For example, the external connectors 142 can represent solder bumps or balls.

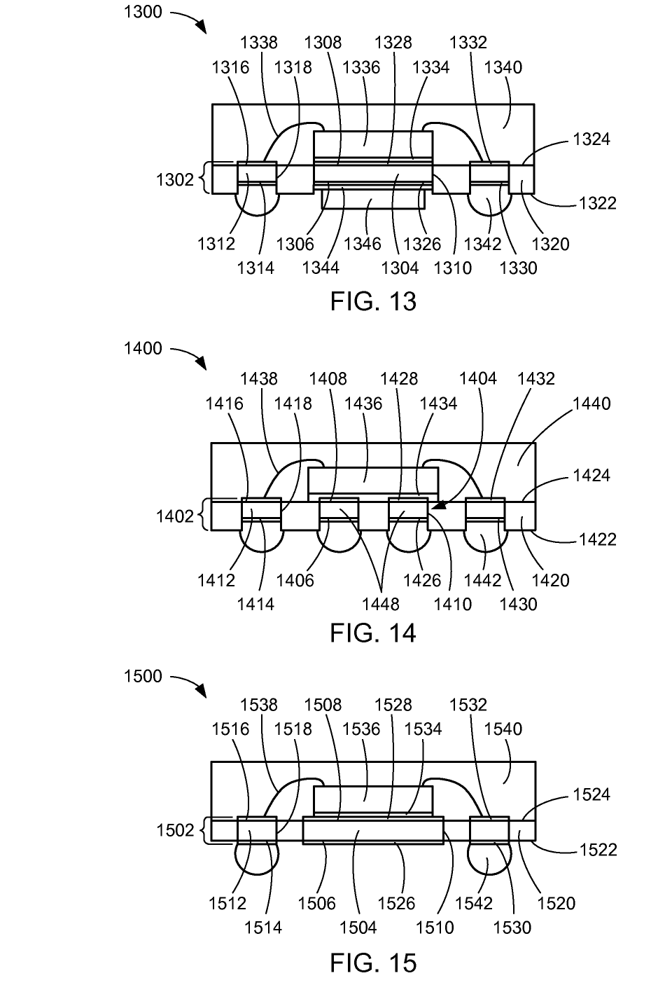

Referring now to FIG. 13, therein is shown a cross-sectional view of an integrated circuit packaging system 1300 in a second embodiment of the present invention. In a manner similar to the integrated circuit packaging system 100 of FIG. 1, the integrated circuit packaging system 1300 includes a single-layer substrate 1302.

In a manner similar to the integrated circuit packaging system 100, the single-layer substrate 1302 includes a single-layer support structure 1304 having a structure lower surface 1306, a structure upper surface 1308, and a structure non-horizontal surface 1310. In a manner similar to the integrated circuit packaging system 100, the single-layer substrate 1302 includes single-layer contacts 1312, each of which having a contact lower surface 1314, a contact upper surface 1316, and a contact non-horizontal surface 1318.

In a manner similar to the integrated circuit packaging system 100, the single-layer substrate 1302 includes a single-layer insulation 1320 having an insulation lower surface 1322 and an insulation upper surface 1324. In a manner similar to the integrated circuit packaging system 100, the single-layer substrate 1302 includes a lower support pad 1326, an upper support pad 1328, lower contact pads 1330, and upper contact pads 1332.

In a manner similar to the integrated circuit packaging system 100, the integrated circuit packaging system 1300 includes an attach layer 1334 and an integrated circuit 1336. In a manner similar to the integrated circuit packaging system 100, the integrated circuit packaging system 1300 includes internal connectors 1338, an encapsulation 1340, and external connectors 1342.

The integrated circuit packaging system 1300 also includes an adhesive layer 1344 for thermally connecting or attaching a heat spreader 1346 to the lower support pad 1326 directly on the structure lower surface 1306. The lower support pad 1326 can represent a thermal contact pad under the upper support pad 1328.

The adhesive layer 1344 can be formed with an attach material including a thermally conductive material or a thermally conductive paste. Heat generated by the integrated circuit 1336 can be conducted away from the integrated circuit 1336 to ambient through the attach layer 1334, the upper support pad 1328, the single-layer support structure 1304, the lower support pad 1326, the adhesive layer 1344, and the heat spreader 1346.

For illustrative purposes, the insulation lower surface 1322 is shown below the structure lower surface 1306 and the contact lower surface 1314, although it is understood that the insulation lower surface 1322 can be formed in any configuration. For example, the insulation lower surface 1322 can optionally be coplanar with the structure lower surface 1306 and the contact lower surface 1314.

It has been discovered that the single-layer insulation 1320 provides improved structural integrity with the single-layer insulation 1320 horizontally between the structure non-horizontal surface 1310 and the contact non-horizontal surface 1318 or horizontally between the contact non-horizontal surface 1318 and another of the contact non-horizontal surface 1318 to provide firm mounting and attaching support as well as provide process advantage and cost advantage.

It has also been discovered that the structure upper surface 1308, the contact upper surface 1316, and the insulation upper surface 1324 coplanar with each other provides improved reduction of package height profile since the single-layer insulation 1320 is not formed directly over the single-layer support structure 1304 and the single-layer contacts 1312.

It has further been discovered that the single-layer insulation 1320 having the extension that vertically extends beyond the single-layer support structure 1304 and the single-layer contacts 1312 provides improved reliability because the extension eliminates electrical shorts among the single-layer support structure 1304 and the single-layer contacts 1312.

It has further been discovered that the structure non-horizontal surface 1310 and the contact non-horizontal surface 1318 having the physical characteristic described above provides improved structural integrity by providing improved adhesion for the single-layer insulation 1320 to form thereby eliminating the single-layer support structure 1304 and the single-layer contacts 1312 from being pulled out.

It has further been discovered that the adhesive layer 1344 attached to the heat spreader 1346 and the lower support pad 1326 provides improved reliability with the adhesive layer 1344 and the heat spreader 1346 conducting the heat away from the integrated circuit 1336.

Referring now to FIG. 14, therein is shown a cross-sectional view of an integrated circuit packaging system 1400 in a third embodiment of the present invention. In a manner similar to the integrated circuit packaging system 100 of FIG. 1, the integrated circuit packaging system 1400 includes a single-layer substrate 1402.

The single-layer substrate 1402 includes a single-layer support structure 1404 having a structure lower surface 1406, a structure upper surface 1408, and a structure non-horizontal surface 1410. In a manner similar to the integrated circuit packaging system 100, the single-layer substrate 1402 includes single-layer contacts 1412, each of which having a contact lower surface 1414, a contact upper surface 1416, and a contact non-horizontal surface 1418.

In a manner similar to the integrated circuit packaging system 100, the single-layer substrate 1402 includes a single-layer insulation 1420 having an insulation lower surface 1422 and an insulation upper surface 1424. The single-layer substrate 1402 includes lower support pads 1426 and upper support pads 1428. In a manner similar to the integrated circuit packaging system 100, the single-layer substrate 1402 includes lower contact pads 1430 and upper contact pads 1432.

In a manner similar to the integrated circuit packaging system 100, the integrated circuit packaging system 1400 includes an attach layer 1434 and an integrated circuit 1436. In a manner similar to the integrated circuit packaging system 100, the integrated circuit packaging system 1400 includes internal connectors 1438, an encapsulation 1440, and external connectors 1442.

The single-layer support structure 1404 can be formed with a plurality of isolated support structures 1448 that are structurally separated from each other. Each of the isolated support structures 1448 is defined as a structure having only one contiguously solid layer of a conductive material. The isolated support structures 1448 as a whole provide support for attaching and mounting the integrated circuit 1436 directly thereover.

Each of the isolated support structures 1448 can include the structure lower surface 1406 and the structure upper surface 1408. One of the lower support pads 1426 and one of the upper support pads 1428 can be formed directly on the structure lower surface 1406 and the structure upper surface 1408, respectively.

The attach layer 1434 can be formed directly on the upper support pads 1428 and a portion of the insulation upper surface 1424. The upper support pads 1428 and the portion of the insulation upper surface 1424 provide a mount region including a die receiving area for mounting the integrated circuit 1436. The mount region can be adjacent the single-layer contacts 1412 and the upper contact pads 1432. The upper support pads 1428 can be within the mount region.

The external connectors 1442 can be attached to the lower support pads 1426 directly on the isolated support structures 1448 at the structure lower surface 1406. Heat generated by the integrated circuit 1436 can be conducted away from the integrated circuit 1436 to an external system (not shown) through the attach layer 1434, the upper support pads 1428, the isolated support structures 1448, the lower support pads 1426, and the external connectors 1442.

The lower support pads 1426 under the mount region can represent thermal contact pads or through contact pads for providing thermal connection to the external system. The upper support pads 1428 can represent die support pads for providing mounting support for the integrated circuit 1436.

For illustrative purposes, the insulation lower surface 1422 is shown below the structure lower surface 1406 and the contact lower surface 1414, although it is understood that the insulation lower surface 1422 can be formed in any configuration. For example, the insulation lower surface 1422 can optionally be coplanar with the structure lower surface 1406 and the contact lower surface 1414.

It has been discovered that the single-layer insulation 1420 provides improved structural integrity with the single-layer insulation 1420 horizontally between the structure non-horizontal surface 1410 and the contact non-horizontal surface 1418 or horizontally between the contact non-horizontal surface 1418 and another of the contact non-horizontal surface 1418 to provide firm mounting and attaching support as well as provide process advantage and cost advantage.

It has also been discovered that the structure upper surface 1408, the contact upper surface 1416, and the insulation upper surface 1424 coplanar with each other provides improved reduction of package height profile since the single-layer insulation 1420 is not formed directly over the single-layer support structure 1404 and the single-layer contacts 1412.

It has further been discovered that the single-layer insulation 1420 having the extension that vertically extends beyond the single-layer support structure 1404 and the single-layer contacts 1412 provides improved reliability because the extension eliminates electrical shorts among the single-layer support structure 1404 and the single-layer contacts 1412.

It has further been discovered that the structure non-horizontal surface 1410 and the contact non-horizontal surface 1418 having the physical characteristic described above provides improved structural integrity by providing improved adhesion for the single-layer insulation 1420 to form thereby eliminating the single-layer support structure 1404 and the single-layer contacts 1412 from being pulled out.

It has further been discovered that the single-layer support structure 1404 having a number of the isolated support structures 1448 provide improved reliability with the isolated support structures 1448 providing multiple heat conduction paths for the heat to be conducted away from the integrated circuit 1436.

Referring now to FIG. 15, therein is shown a cross-sectional view of an integrated circuit packaging system 1500 in a fourth embodiment of the present invention. In a manner similar to the integrated circuit packaging system 100 of FIG. 1, the integrated circuit packaging system 1500 includes a single-layer substrate 1502.

In a manner similar to the integrated circuit packaging system 100, the single-layer substrate 1502 includes a single-layer support structure 1504 having a structure lower surface 1506, a structure upper surface 1508, and a structure non-horizontal surface 1510. In a manner similar to the integrated circuit packaging system 100, the single-layer substrate 1502 includes single-layer contacts 1512, each of which having a contact lower surface 1514, a contact upper surface 1516, and a contact non-horizontal surface 1518.

In a manner similar to the integrated circuit packaging system 100, the single-layer substrate 1502 includes a single-layer insulation 1520 having an insulation lower surface 1522 and an insulation upper surface 1524. In a manner similar to the integrated circuit packaging system 100, the single-layer substrate 1502 includes a lower support pad 1526, an upper support pad 1528, lower contact pads 1530, and upper contact pads 1532.

In a manner similar to the integrated circuit packaging system 100, the integrated circuit packaging system 1500 includes an attach layer 1534 and an integrated circuit 1536. In a manner similar to the integrated circuit packaging system 100, the integrated circuit packaging system 1500 includes internal connectors 1538, an encapsulation 1540, and external connectors 1542.

The single-layer insulation 1520 can be formed with the insulation lower surface 1522 coplanar with the structure lower surface 1506 and the contact lower surface 1514. The single-layer substrate 1502 having a vertical thickness predetermined with a vertical height of the single-layer support structure 1504, each of the single-layer contacts 1512, or the single-layer insulation 1520 provides a thinner support structure compared to the single-layer substrate 102 of FIG. 1.

The lower contact pads 1530 can be below the single-layer insulation 1520. The external connectors can be directly on only the lower contact pads 1530 since the insulation lower surface 1522 is coplanar with the structure lower surface 1506 and the contact lower surface 1514.

It has been discovered that the single-layer insulation 1520 provides improved structural integrity with the single-layer insulation 1520 horizontally between the structure non-horizontal surface 1510 and the contact non-horizontal surface 1518 or horizontally between the contact non-horizontal surface 1518 and another of the contact non-horizontal surface 1518 to provide firm mounting and attaching support as well as provide process advantage and cost advantage.

It has also been discovered that the structure upper surface 1508, the contact upper surface 1516, and the insulation upper surface 1524 coplanar with each other provides improved reduction of package height profile since the single-layer insulation 1520 is not formed directly over the single-layer support structure 1504 and the single-layer contacts 1512.

It has further been discovered that the structure non-horizontal surface 1510 and the contact non-horizontal surface 1518 having the physical characteristic described above provides improved structural integrity by providing improved adhesion for the single-layer insulation 1520 to form thereby eliminating the single-layer support structure 1504 and the single-layer contacts 1512 from being pulled out.

It has further been discovered that the insulation lower surface 1522 coplanar with the structure lower surface 1506 and the contact lower surface 1514 provides improved package height profile by reducing thickness of the single-layer substrate 1502 based on the vertical height of the single-layer support structure 1504, each of the single-layer contacts 1512, and the single-layer insulation 1520.

It has further been discovered that the external connectors 1542 directly on only the lower contact pads 1530 provides improved reliability since the lower contact pads 1530 provides improved adhesion property for the external connectors 1542 to firmly adhere thereto compared to an adhesion property of the single-layer insulation 1520.

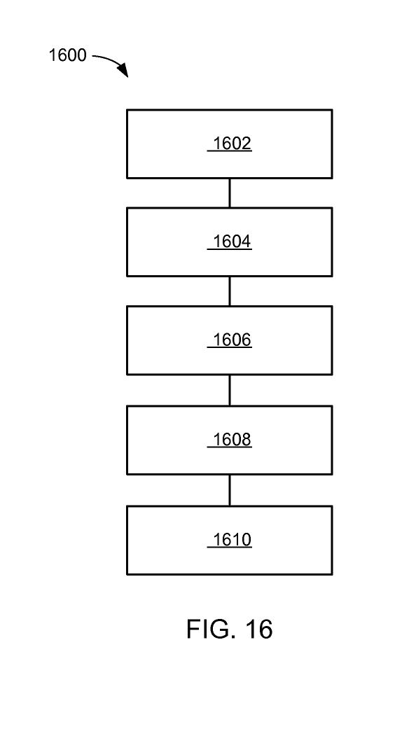

Referring now to FIG. 16, therein is shown a flow chart of a method 1600 of manufacture of the integrated circuit packaging system 100 of FIG. 1 in a further embodiment of the present invention. The method 1600 includes: providing a single-layer support structure having a structure non-horizontal surface in a block 1602; forming a single-layer contact coplanar with the single-layer support structure, the single-layer contact having a contact non-horizontal surface in a block 1604; forming a single-layer insulation coplanar with the single-layer contact and horizontally between the structure non-horizontal surface and the contact non-horizontal surface in a block 1606; forming an upper support pad over the single-layer insulation and directly on the single-layer support structure in a block 1608; and mounting an integrated circuit over the upper support pad in a block 1610.

Thus, it has been discovered that the integrated circuit packaging system of the present invention furnishes important and heretofore unknown and unavailable solutions, capabilities, and functional aspects for an integrated circuit packaging system with support structure. The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems fully compatible with conventional manufacturing methods or processes and technologies.

Another important aspect of the present invention is that it valuably supports and services the historical trend of reducing costs, simplifying systems, and increasing performance.

These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
providing a single-layer support structure having a structure non-horizontal surface;
forming a single-layer contact coplanar with the single-layer support structure, the single-layer contact having a contact non-horizontal surface;
forming a single-layer insulation coplanar with the single-layer contact and horizontally between the structure non-horizontal surface and the contact non-horizontal surface;
forming an upper support pad over the single-layer insulation and directly on the single-layer support structure; and
mounting an integrated circuit over the upper support pad.

2. The method as claimed in claim 1 wherein forming the single-layer insulation includes forming the single-layer insulation having an insulation lower surface below the single-layer contact.

3. The method as claimed in claim 1 wherein forming the single-layer insulation includes forming the single-layer insulation having an insulation lower surface coplanar with a contact lower surface of the single-layer contact.

4. The method as claimed in claim 1 further comprising attaching a heat spreader to the single-layer support structure.

5. The method as claimed in claim 1 wherein:
providing the single-layer support structure includes providing the single-layer support structure having an isolated support structure; and
mounting the integrated circuit includes mounting the integrated circuit directly over the isolated support structure.

6. A method of manufacture of an integrated circuit packaging system comprising:
providing a single-layer support structure having a structure non-horizontal surface;
forming a single-layer contact coplanar with the single-layer support structure, the single-layer contact having a contact non-horizontal surface;
forming a single-layer insulation coplanar with the single-layer contact and horizontally between the structure non-horizontal surface and the contact non-horizontal surface;
forming an upper support pad over the single-layer insulation and directly on the single-layer support structure;
mounting an integrated circuit over the upper support pad; and
forming an encapsulation over the integrated circuit and directly on the single-layer insulation.

7. The method as claimed in claim 6 wherein forming the single-layer insulation includes forming the single-layer insulation horizontally between the contact non-horizontal surface and another of the contact non-horizontal surface, the single-layer insulation having an insulation lower surface below the single-layer contact.

8. The method as claimed in claim 6 wherein forming the single-layer insulation includes forming the single-layer insulation having an insulation lower surface coplanar with a contact lower surface of the single-layer contact and a structure lower surface of the single-layer support structure.

9. The method as claimed in claim 6 further comprising:
forming a lower support pad directly on the single-layer support structure; and
attaching a heat spreader to the lower support pad.

10. The method as claimed in claim 6 wherein:
providing the single-layer support structure includes providing the single-layer support structure having an isolated support structure; and
mounting the integrated circuit includes mounting the integrated circuit directly over the isolated support structure; and
further comprising:
attaching an external connector to the single-layer support structure.

11. An integrated circuit packaging system comprising:
a single-layer support structure having a structure non-horizontal surface;
a single-layer contact coplanar with the single-layer support structure, the single-layer contact having a contact non-horizontal surface;
a single-layer insulation coplanar with the single-layer contact and horizontally between the structure non-horizontal surface and the contact non-horizontal surface;
an upper support pad over the single-layer insulation and directly on the single-layer support structure; and
an integrated circuit over the upper support pad.

12. The system as claimed in claim 11 wherein the single-layer insulation includes an insulation lower surface below the single-layer contact.

13. The system as claimed in claim 11 wherein the single-layer insulation includes an insulation lower surface coplanar with a contact lower surface of the single-layer contact.

14. The system as claimed in claim 11 further comprising a heat spreader attached to the single-layer support structure.

15. The system as claimed in claim 11 wherein:
the single-layer support structure includes an isolated support structure; and
the integrated circuit is directly over the isolated support structure.

16. The system as claimed in claim 11 further comprising an encapsulation over the integrated circuit and directly on the single-layer insulation.

17. The system as claimed in claim 16 wherein the single-layer insulation is horizontally between the contact non-horizontal surface and another of the contact non-horizontal surface, the single-layer insulation having an insulation lower surface below the single-layer contact.

18. The system as claimed in claim 16 wherein the single-layer insulation includes an insulation lower surface coplanar with a contact lower surface of the single-layer contact and a structure lower surface of the single-layer support structure.

19. The system as claimed in claim 16 further comprising:
a lower support pad directly on the single-layer support structure; and
a heat spreader attached to the lower support pad.

20. The system as claimed in claim 16 wherein:
the single-layer support structure includes an isolated support structure; and
the integrated circuit is directly over the isolated support structure; and
further comprising:
an external connector attached to the single-layer support structure.
